(19) United States
(12) Patent Application Publication
(10) Pub. No.: US 2010/0019325 A1
(43) Pub. Date: Jan. 28, 2010

(54) SEMICONDUCTOR DEVICE

(76) Inventors: Hidetatsu Nakamura, Tokyo (JP); Kazuya Uejima, Tokyo (JP)

Correspondence Address: Mr. Jackson Chen, 6535 N. STATE HWY 161, IRVING, TX, 75039, US

(21) Appl. No.: 12/529,879

(22) PCT Filed: Mar. 3, 2008
(86) PCT No.: PCT/JP2008/053780

§ 371 Date: Sep. 3, 2009

(30) Foreign Application Priority Data
Mar. 5, 2007 (JP) 2007-054037

(51) Int. Cl. H01L 27/092

(52) U.S. Cl. 257/369; 257/E27.062

(57) ABSTRACT

In a semiconductor device, a contact stopper film having a stress is provided to cover a group of MISFETs arranged in a gate-length direction. The stopper film has an extension part that extends by a length L=1 μm or more toward the outside of the gate electrode of the MISFET located the endmost part of the MISFET group.

### TECHNICAL FIELD

The present invention relates a semiconductor device and, more particularly, to the structure of a semiconductor device including MISFETs for which a stress-containing film that applies a strain onto the channel area is formed.

### BACKGROUND ART

In recent years, the throughput capacity required of an LSI is increasingly raised together with the development of information-communication apparatus, whereby a higher speed of transistors is sought. Although the higher speed has been heretofore achieved mainly by a reduction in the dimension of structure, it has become difficult to reduce the gate length due to the limit of the lithographic technology, and a thinner structure of the gate insulation film is difficult to achieve due to physical factors. Thus, a new technique for seeking a higher throughput capacity other than the dimensional reduction is needed. As one of such techniques, a technique that takes advantage of the piezoresistance effect wherein a stress is applied to the channel of a field-effect-transistor (MISFET) to distort the channel and thus raise the mobility.

If a tensile stress (compressive stress) is applied to the channel of the MISFET for a strain in the direction parallel to the channel, the mobility of electrons is improved (degraded) whereas the mobility of holes is degraded (improved). As the technique using this phenomenon, in JP-2002-198368A for example, a nitride film is used as a contact stopper film, which is caused to have a strong tensile stress and distort the channel, for improving the mobility of n-channel MISFET. In addition, in JP-2003-086708A, by using a nitride film having a tensile strain in an n-channel MISFET and a nitride film having a compressive stress in a p-channel MISFET, as the contact stopper film, the mobility of both the n-channel and p-channel MISFETs is improved.

In a semiconductor device, such as described in JP-2003-086708A, using the nitride film having a tensile stress in the n-channel MISFET and the nitride film having a compressive stress in the p-channel MISFET, there arises a problem that in an area wherein the n-channel MISFET and p-channel MISFET are disposed adjacent to each other, there exist nitride films having opposite stress polarities in the vicinity of each transistor, to thereby cancel the stress applied onto the channel.

It is possible to improve the mobility of a single MISFET and thereby to improve the performance thereof, by employing the technique described in JP-2003-086708A. However, it is sometimes difficult to apply an effective stress onto the channel of all the MISFETs and to improve the overall performance as the circuit level thereof, only by using the technique described in JP-2003-086708A alone.

### SUMMARY OF THE INVENTION

In view of the above, it is an object of the present invention to improve a semiconductor device including a stress-containing film that applies a stress onto the channel of MISFETs, and to thereby provide a semiconductor device including a stress-containing film that is improved to be able to apply an effective stress onto the channel of MISFETs in the entire circuit.

The present invention provides a semiconductor device including a plurality of MISFETs covered by a stress-containing film, wherein the plurality of MISFETs include a group of MISFETs arranged in a gate-length direction, and the stress-containing film includes an extension part that extends by 1 μm or more toward outside of the group of MISFETs at the end portion of the group of MISFETs as viewed in the gate-length direction.

The above and other objects, features and advantages of the present invention will be more apparent from the following description, referring to the accompanying drawings.

### BRIEF DESCRIPTION OF THE DRAWINGS

FIGS. 1A and 1B are a top plan view and a sectional view, respectively, showing the layout of MISFETs and a contact stopper film in a semiconductor device according to a first embodiment of the present invention.

FIG. 2 is a top plan view showing the layout of MISFETs and a contact stopper film in a semiconductor device according to a modified example of the first embodiment of the present invention.

FIG. 3 is a top plan view showing the layout of CMOSFETs and a contact stopper film in a semiconductor device according to a second embodiment of the present invention.

FIG. 4 is a graph showing the relationship between the length of the nitride film applying the stress onto the channel of MOSFETs and the stress applied to the channel.

FIG. 5 is a sectional view of a MOSFET for showing the length of the nitride film.

FIG. 6 is a graph showing the relationship between the length of the nitride film that applies the stress onto the channel of MOSFETs and the ON-current.

### DETAILED DESCRIPTION OF THE INVENTION

Hereinafter, exemplary embodiments of the present invention will be described in detail with reference to the drawings.

### First Embodiment

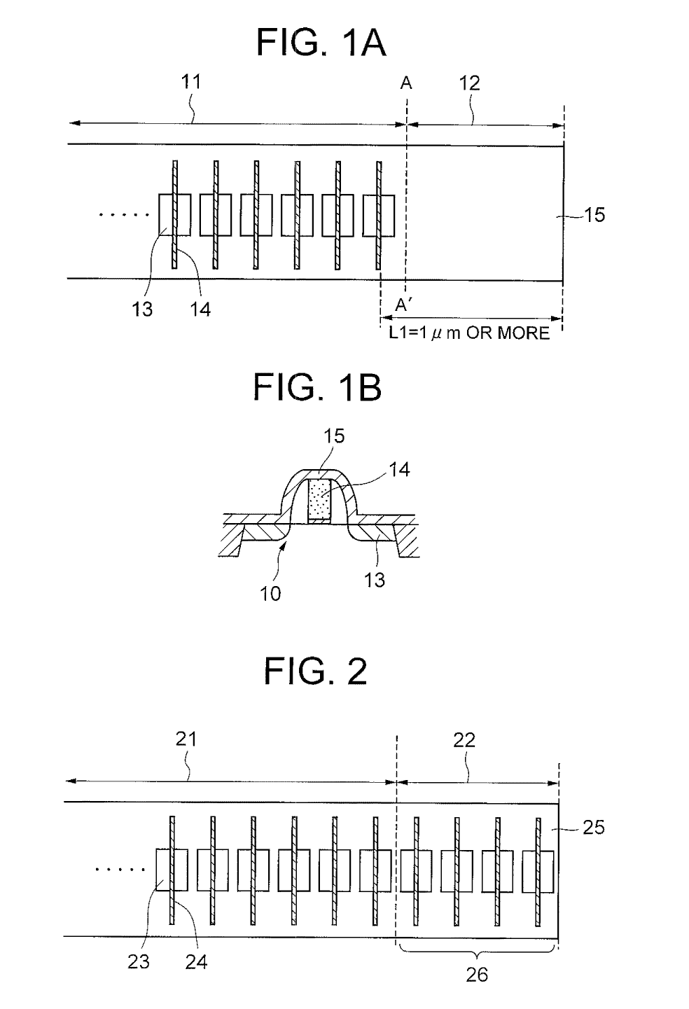

FIGS. 1A and 1B are a top plan view and a sectional view, respectively, showing a semiconductor device according to a first embodiment of the present invention. The same drawings show the end structure of a group of MISFETs arranged in the direction of the gate length among the MISFETs (MOSFETS) formed therein together with the layout of a contact stopper film. Each MISFET includes source/drain diffused regions 13, and a gate electrode 14, and is arranged in the gate-length direction to configure the MISFET group 11. In this specification, the term “gate-length direction” is synonymous with the extending direction of the channel of MISFET. The contact stopper film 15 has an internal stress, covers the MISFET group 11, and applies a stress onto the channel of each MISFET. The stopper film 15 is configured as a stress-containing film that includes a silicon nitride film, and includes a stress-containing-film extension part 12 that extends toward the outside by a distance of L1=1 μm as measured from the sidewall of the gate electrode 14 of the MISFET located at the endmost part of the MISFET group 11. That is, the stress-containing film includes an extension part 12 that extends toward the outside of the MISFET group by a length of 1 μm or more. Since the stopper film 15 has a thickness of about tens of nanometers, for example, and the width of the sidewall is also tens of nanometers, there is substantially no difference irrespective of whether the distance of 1 μm for the extension part is measured from the gate sidewall or from the end of the gate.

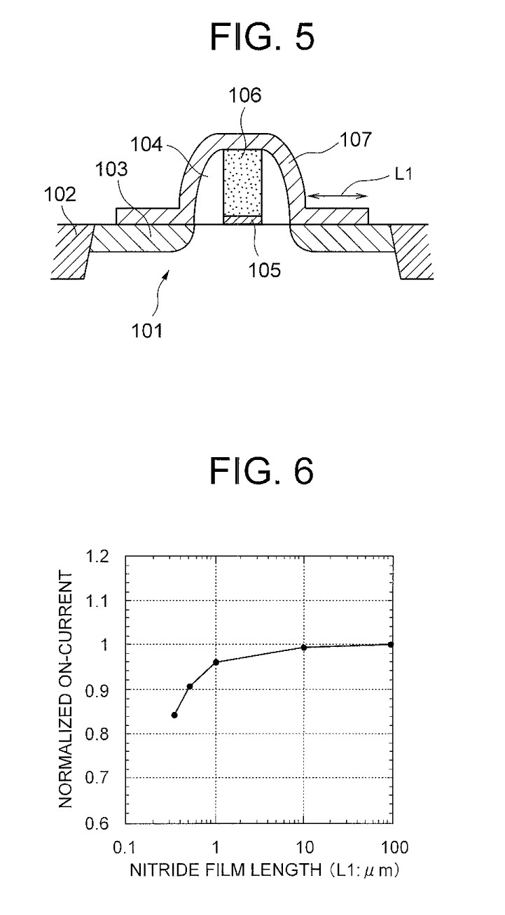

The function of advantage obtained by employing the above structure will be described with reference to FIGS. 4 to 6. FIG. 4 shows a calculation result showing how far from the channel the nitride film contributes to the channel stress. A two-dimensional stress simulator was used for this calculation. FIG. 5 shows the structure of an n-channel MISFET in a sectional view. The n-channel MISFETs are formed on a silicon substrate 101, and are isolated from one another by an element-isolating insulation film 102. The MISFETs include source/drain diffused regions 103, source/drain extension regions 108, a gate insulation film 105, a gate electrode 106, and a sidewall 104, which are formed in the silicon substrate 10, and a nitride film 107 having a tensile stress is formed thereon.

The structure of FIG. 5 employs a nitride film 107 having a tensile stress. The nitride-film length plotted on the abscissa shown in FIG. 4 is the length L1 of the nitride film 107, as shown in FIG. 5, which is measured from the side surface of the nitride film 107, formed to cover the sidewall 104, along the channel to the end thereof, as shown in FIG. 5. The channel stress on the ordinate is such that the tensile stress is positive. It is understood from FIG. 4 that the nitride film should have a length of around 5 μm in order for the channel to fully receive the benefit of the stress of the nitride film.

The nitride film itself having a higher Young's modulus has an alleviated internal stress if the channel is strained. Especially, a portion of the nitride film in the vicinity of the gate electrode has a significantly alleviated internal stress and loses the power for distorting the channel. For this reason, a portion of the nitride film which is significantly apart from the gate electrode and does not have an alleviated internal stress contributes to the channel stress. Thus, the portion of the nitride film that is relatively apart from the gate electrode, i.e., the portion of the nitride film that is apart from the sidewall by around 5 μm in the graph of FIG. 4 also contributes to the channel stress. FIG. 6 shows, in relation to this, the result of experiment as to how far from the channel the nitride film contributed to the channel stress. The definition of abscissa is the same as FIG. 4, and the ordinate shows the normalized ON-current of the MISFET. It is understood from FIG. 6 that, if the length (L1) of the nitride film is 1 μm or less, the ON-current significantly deteriorates. This result duplicates the result of calculation in FIG. 4 qualitatively.

In the embodiment shown in FIGS. 1A and 1B, the stopper film 15 having a stress extends by a sufficient length toward the outside in the gate-length direction of the group 11 of MISFETs arranged in the gate-length direction. For this reason, a sufficient stress is applied also onto the MISFET located at the end portion of the MISFET group in the gate-length direction (column direction). Even if there exists a MISFET group having an opposite electric conductivity and covered by the stopper film that is located adjacent thereto in the column direction and has an opposite stress, the channel stress does not decline as shown in FIG. 4, and as a result, the ON-current does not deteriorate, as shown in FIG. 6. Therefore, a desired stress can be obtained in the channel of MISFETs in the entire circuit. Thus, MISFETs having a higher ON-current can be obtained in the entire circuit.

Note that as the contact stopper film 15, a stress-containing film having a tensile stress and a stress-containing film having a compressive stress are effective in the n-channel MISFETs and p-channel MISFETs, respectively, for improving the performance of the MISFETs. This is because the film having a tensile stress applies a tensile stress onto the channel of the n-channel MISFETs to raise the mobility of electrons, and the film having a compressive stress applies a compressive stress onto the channel of the p-channel MISFETs to raise the mobility of holes.

Note that the advantage achieved in samples of the embodiment of the present invention can be assured using a convergent beam electron diffraction, for example, as described in JP-2000-9664A. This technique irradiates convergent electrons onto the samples to find the strained amount thereof from the diffracted figure obtained, and can measure the strain of a specific site with a spatial resolution of about 10 nm. In the samples of the embodiment, the advantage can be assured by comparing the amount of strain measured by the convergent beam electron diffraction between the MISFET located at the center and the MISFET located at the end of the MISFET group.

Next, a manufacturing method of the semiconductor device according to the present embodiment will be described. The fabrication process up to deposition of the contact stopper film is similar to that of the typical MISFETs, and thus will be omitted here for description. The fabrication process of a semiconductor device using a tensile-stress film in the n-channel MISFETs and a compressive-stress film in the p-channel MISFETs is basically manufactured using a process such as described in JP-2003-60076A, and thus omitted herein for description.

As the contact stopper film, the film having a tensile stress is typically a silicon nitride film formed using a thermochemical vapor deposition technique or atomic layer deposition technique, and the film having a compressive stress is typically a silicon nitride film formed using a plasma-enhanced chemical vapor deposition technique. As the other films, silica compound represented by silicon nitride, such as including either of carbon, hydrogen, oxygen, and nitrogen, or an oxide represented by silicon oxide, such as including either of aluminum, hafnium, tantalum, zirconium, silicon, and nitrogen is enumerated. Basically, by changing only the arrangement of MISFETs and arrangement of the stopper film, the semiconductor device according to the embodiment can be manufactured.

FIG. 2 shows a modified example of the above embodiment. In this modified example, a dummy structure 26 is arranged in which dummy diffused regions and dummy gates having a structure similar to the structure of the source/drain diffused region 23 and gate electrode 24, respectively, of MISFETs are formed. Here, the dummy diffused regions and dummy gates mean a structure which exists in a circuit as a structure similar to the regular diffused regions and gates, yet for which no interconnection lines are installed, and which exists as a structure completely independent from the circuit of other MISFETs. Existence of the dummy diffused regions and dummy gates can reduce the range of characteristic variation attributable to the stress in the MISFET located at the end of the MISFET group 21.

### Second Embodiment

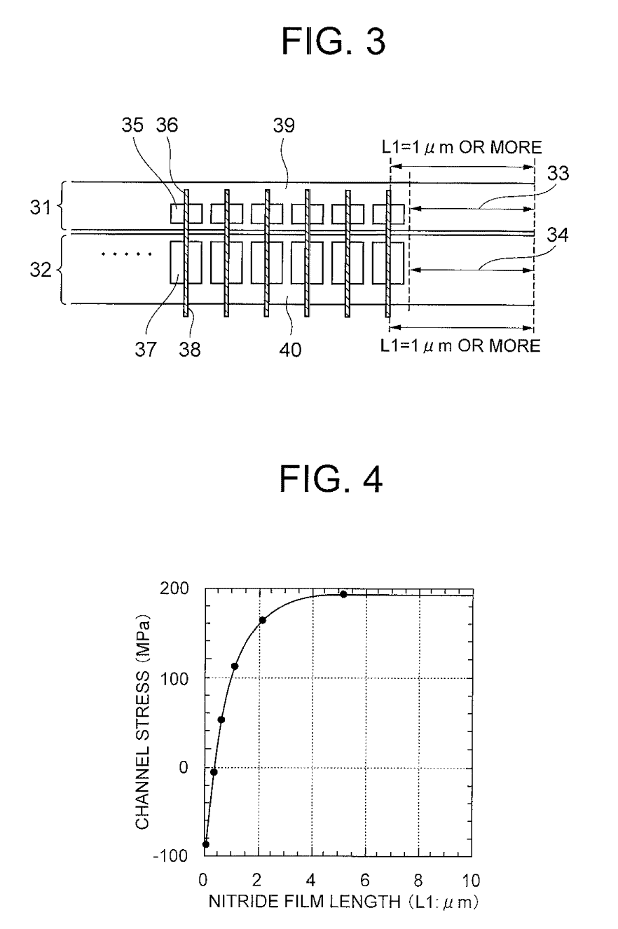

FIG. 3 shows a semiconductor device according to a second embodiment of the present invention. In the present embodiment, the semiconductor device is configured as a CMOS semiconductor device, and includes an n-channel MOSFET group 31 and a p-channel MOSFET group 32 arranged in the gate-length direction, wherein these MOSFET groups 31 and 32 are located adjacent to each other. The n-channel MOSFETs include source/drain 35 and a gate electrode 36, whereas the p-channel MOSFETs include source/drain diffused regions 37 and a gate electrode 38. The contact stopper film 39 having a tensile stress covers the n-channel MOSFET group 31 whereas the contact stopper film 40 having a compressive strain covers the p-channel MOSFET group 32. In addition, both the stopper films 39 and 40 have extensions 33 and 34 that extend by 1 μm or more toward the outside of sidewall of the gate electrode of the MOSFET located at the endmost portion of the n-channel MOSFET group 31 and p-channel MOSFET group 32, respectively.

Since the stopper film 39 having a tensile stress extends by a sufficient length toward outside of the n-channel MOSFET group 31, even if there exists a MOSFET group that is located adjacent thereto and covered by a stopper film having a compressive stress, the channel stress does not decline as shown in FIG. 4, similarly to the first embodiment. As a result, degradation of the ON-current such as shown in FIG. 6 will not occur. Similarly, since the stopper film 40 having a compressive stress extends by a sufficient length toward outside of the p-channel MOSFET group 32, even if there exists a MOSFET group that is located adjacent thereto and covered by a stopper film having a tensile stress, the channel stress does not decline as shown in FIG. 4, similarly to the first embodiment. As a result, degradation of the ON-current such as shown in FIG. 6 will not occur. Accordingly, a desired stress is applied onto the MISFETs in the entire circuit, whereby it is possible to achieve a CMOSFET having a higher ON-current.

As described above, a film having a tensile stress is effective in the n-channel MOSFET whereas a film having a compressive stress is effective in the p-channel MOSFET for improving the performance of MOSFETs, as the contact stopper films 39 and 40. This is because the film having a tensile stress applies a tensile strain onto the channel of MOSFETs to improve the mobility of electrons (n-channel MOSFETs) whereas the film having a compressive stress applies a compressive strain onto the channel of MOSFETs to improve the mobility of holes (p-channel MOSFETs).

Next, a fabrication process of the semiconductor device according to the present embodiment will be described. The process up to deposition of the contact stopper film is similar to the fabrication process of a typical CMOSFET, and thus is omitted here for description. The tensile-stress film is used for the n-channel MOSFET and the compressive-stress film is used for the p-channel MOSFET, as the contact stopper film. The fabrication process of a semiconductor device having such a structure can be manufactured basically using the fabrication process described in JP-2003-60076A, for example, and thus will be omitted here for description.

The film having a tensile stress is mainly configured, as the contact stopper film, by a silicon nitride film formed by a thermochemical vapor deposition technique or an atomic-layer deposition technique. The film having a compressive stress is mainly configured by a silicon nitride film formed by a plasma-enhanced chemical vapor deposition technique. As films other than those films, silica compound represented by silicon nitride, for example, including either of carbon, hydrogen, oxygen, and nitrogen, or oxides of aluminum, hafnium, tantalum, zirconium, silicon, and nitrogen, represented by silicon oxide is enumerated. Fundamentally, the semiconductor device according to the present embodiment can be manufactured by changing the arrangement of MOSFETs and arrangement of the stopper film.

It is possible to arrange the dummy diffused regions and dummy gates on the extension part of the contact stopper film, as a modified example of the present embodiment, similarly to the modified example of the first embodiment. Existence of the dummy diffused regions and dummy gates can reduce the range of characteristic variation attributable to the stress of MISFET located at the end portion of the MOSFET group.

In the semiconductor device of the above embodiment, it is easy to apply a desired stress onto the MISFETs in the entire circuit, and it is possible to achieve MISFETs having a higher ON-current and a uniform characteristic. More specifically, since the stress of the stress-containing film is effectively applied onto the channel at the end portion of the MISFET group in the semiconductor device, n-channel MISFETs and/or p-channel MISFETs having a higher ON-current can be achieved in the entire circuit of the semiconductor device.

As described heretofore, the following embodiments may be employed in the present invention.

In the semiconductor device of the present invention, a configuration may be employed wherein the MISFETs include n-channel MISFETs, and the stress-containing film has a tensile stress. In this case, the n-channel MISFETs are applied with a tensile stress whereby mobility and ON-current can be improved.

In addition, a configuration may be employed wherein the MISFETs include p-channel MISFETs, and the stress-containing film has a compressive stress. In this case, a compressive stress is applied onto the p-channel MISFET to improve the mobility and ON-current.

In addition, a configuration may be employed wherein a dummy diffused region or a dummy gate is arranged in the extension part of the stress-containing film. This reduces the range of characteristic variation of MISFET located at the end portion of the MISFET group.

In addition, it is preferable that the stress-containing film be an insulation film. In this case, a configuration may be employed wherein the insulation film includes at least one compound selected from hydrocarbon, silicon hydride, silicon oxide, silicon nitride, aluminum oxide, hafnium oxide, tantalum oxide, zirconium oxide, and nitrogen oxide.

A configuration may be employed wherein the group of MISFETs include an n-channel MISFET group and a p-channel MISFET group, and the extension part of the stress-containing film is formed at an end portion of each of the n-channel MISFET group and the p-channel MISFET group. In this case, since the stress of the stopper film is effectively applied onto the channel at the end portion of the p-channel and n-channel MISFET groups, it is possible to achieve n-channel MISFETs and p-channel MISFETs having a higher ON-current in the entire circuit.

In the above case, a configuration may be employed wherein the stress-containing film that covers the n-channel MISFET group has a tensile stress, and the stress-containing film that covers the p-channel MISFET group has a compressive stress. In this case, a tensile stress is applied onto the n-channel MISFET group, and a compressive stress is applied onto the p-channel MISFET group, whereby mobility and ON-current of both the MISFET groups can be improved.

In the above configuration, a configuration may be employed wherein a dummy diffused region or a dummy gate is provided in the extension part of each stress-containing film in the n-channel MISFET group and the p-channel MISFET group. In this case, the range of characteristic variation of the MISFET located at the end of each MISFET group can be reduced.

While the invention has been particularly shown and described with reference to exemplary embodiment thereof, the invention is not limited to these embodiments and modifications. As will be apparent to those of ordinary skill in the art, various changes may be made in the invention without departing from the spirit and scope of the invention as defined in the appended claims.

This application is based upon and claims the benefit of priority from Japanese patent application No. 2007-054037 filed on Mar. 5, 2007, the disclosure of which is incorporated herein in its entirety by reference.

1. A semiconductor device comprising a plurality of MISFETs covered by a stress-containing film, wherein said plurality of MISFETs include a group of MISFETs arranged in a gate-length direction, and said stress-containing film includes an extension part that extends by 1 μm or more toward outside of said group of MISFETs at the end portion of said group of MISFETs as viewed in the gate-length direction.

2. The semiconductor device according to claim 1, wherein said MISFETs include n-channel MISFETs, and said stress-containing film has a tensile stress.

3. The semiconductor device according to claim 1, wherein said MISFETs include p-channel MISFETs, and said stress-containing film has a compressive stress.

4. The semiconductor device according to claim 1, wherein a dummy diffused region and/or a dummy gate is arranged in said extension part of said stress-containing film.

5. The semiconductor device according to claim 1, wherein said stress-containing film is an insulation film.

6. The semiconductor device according to claim 5, wherein said insulation film includes at least one compound selected from the group consisting of hydrocarbon, silicon hydride, silicon oxide, silicon nitride, aluminum oxide, hafnium oxide, tantalum oxide, zirconium oxide, and nitrogen oxide.

7. The semiconductor device according to claim 1, wherein said group of MISFETs include an n-channel MISFET group and a p-channel MISFET group, and said extension part of said stress-containing film is formed at an end portion of each of said n-channel MISFET group and said p-channel MISFET group.

8. The semiconductor device according to claim 7, wherein said stress-containing film that covers said n-channel MISFET group has a tensile stress, and said stress-containing film that covers said p-channel MISFET group has a compressive stress.

9. The semiconductor device according to claim 7, wherein a dummy diffused region and/or a dummy gate is provided in said extension part of each said stress-containing film in said n-channel MISFET group and said p-channel MISFET group.
